(19) United States
(12) Patent Application Publication
(10) Pub. No.: US 2010/0184279 A1
(43) Pub. Date: Jul. 22, 2010

(54) Method of Making an Epitaxial Structure Having Low Defect Density

(76) Inventors: Dong-Sing Wuu, Taichung City (TW); Ray-Hua Horng, Taichung City (TW); Shih-Ting Chen, Taichung City (TW); Tshung-Han Tsai, Taichung City (TW); Hsueh-Wei Wu, Taichung City (TW)

Correspondence Address: WHYTE HIRSCHBOECK DUDEK S C;INTELLECTUAL PROPERTY DEPARTMENT, 555 EAST WELLS STREET, SUITE 1900, MILWAUKEE, WI, 53202, US

(21) Appl. No.: 12/688,090

(22) Filed: Jan. 15, 2010

(30) Foreign Application Priority Data
Jan. 21, 2009 (TW) 098102239

(51) Int. Cl. H01L 21/20

(52) U.S. Cl. 438/493; 257/E21.09

(57) ABSTRACT

A method of making an epitaxial structure includes: (a) forming laterally a first epitaxial layer on a base layer, the first epitaxial layer having an epitaxial surface; (b) etching the first epitaxial layer using a wet etching agent so that the epitaxial surface has a plurality of first recesses; (c) depositing on the first epitaxial layer a defect-termination layer; and (d) removing the defect-termination layer by a chemical mechanical polishing process, thereby forming a plurality of defect-termination blocks that respectively and fill the first recesses, wherein the defect-termination blocks have polished surfaces that are substantially flush with the epitaxial surface.

### CROSS-REFERENCE TO RELATED APPLICATION

This application claims priority of Taiwanese application No. 098102239, filed on Jan. 21, 2009.

### BACKGROUND OF THE INVENTION

1. Field of the invention

This invention relates to a method of making an epitaxial structure, more particularly to a method of making an epitaxial structure that has a low defect density and that is usable as a substrate for forming a semiconductor device thereon.

2. Description of the related art

In gallium nitride based light-emitting devices, a sapphire substrate or a silicon carbide substrate is usually used for growth of gallium nitride-based layers thereon. During growth of the gallium nitride-based semiconductor layers on the substrate, dislocations due to the lattice mismatching are formed and propagate into the active layer of the light-emitting device, thereby reducing light emitting efficiency thereof.

U.S. Pat. Nos. 6,051,849 and 6,608,327B1 disclose a semiconductor structure including a base layer on which a buffer layer, a first epitaxial layer and a patterned silicon dioxide layer are sequentially stacked. Subsequently, a second epitaxial layer is formed on the first epitaxial layer and the patterned silicon dioxide layer using lateral epitaxial overgrowth techniques. By covering portions of the first epitaxial layer with the patterned silicon oxide layer, defects or dislocations in the second epitaxial layer, which propagate from the first epitaxial layer, can be reduced. Therefore, dislocations formed in the active layer can also be reduced, which results in improvement of light emitting efficiency of the light-emitting device when formed on the semiconductor structure.

However, an increase in epitaxial layers may cause a decrease in yield. In addition, when the number of the epitaxial layer increases, the reduction of the defects attenuates, which fails to effectively improve quantum efficiency of the light-emitting device.

U.S. Patent Application Publication No. 2008/0068291A1 discloses a semiconductor structure including a patterned base layer formed with a plurality of recesses, and a first epitaxial layer formed on the patterned base layer. Subsequently, a patterned mask is stacked on the first epitaxial layer in positions corresponding to recess-free regions for preventing defect propagation therethrough.

U.S. Pat. No. 7,364,805B2 discloses a method of forming spontaneously a plurality of recesses in positions corresponding to dislocations by etching without patterning by a mask. Referring FIGS. 1 to 3, an epitaxial substrate 1 includes a base layer 11, a first epitaxial layer 12, and a coat film 13. The first epitaxial layer 12 has an epitaxial surface 122, a plurality of defects 123, and a plurality of etch pits 121 formed corresponding to the defects 123. The coat film 13 is formed on the epitaxial surface 122 and in the etch pits 121. Then, the coat film 13 formed on the epitaxial surface 122 is removed using reactive ion etching (RIE) techniques for subsequent growth of epitaxial layers thereon. However, defects are prone to increase during removal of the coat film 13 using reactive ion etching techniques. In addition, the etch pits 121 are formed on top ends of the defects including screw dislocations and edge dislocations due to etching by heat and gas.

### SUMMARY OF THE INVENTION

Therefore, an object of the present invention is to provide a method of making an epitaxial structure that can overcome the aforesaid drawbacks associated with the prior art.

According to the present invention, a method of making an epitaxial structure that has a low defect density, comprises: (a) forming laterally a first epitaxial layer on a base layer, the first epitaxial layer having an epitaxial surface and a plurality of concentrated defect groups; (b) etching the first epitaxial layer using a wet etching agent so that the epitaxial surface has a plurality of first recesses corresponding in position to the concentrated defect groups, the sizes of the first recesses being close to each other; (c) depositing on the first epitaxial layer a defect-termination layer having a thickness larger than the depth of the first recesses so that the defect-termination layer fills the first recesses and covers the epitaxial surface, the defect-termination layer being made of a material which is different in removal rate from that of the first epitaxial layer; and (d) removing the defect-termination layer by a chemical mechanical polishing process until the epitaxial surface is exposed, thereby forming a plurality of defect-termination blocks that respectively and completely fill the first recesses, wherein the defect-termination blocks have polished surfaces that are substantially flush with the epitaxial surface.

### BRIEF DESCRIPTION OF THE DRAWINGS

Other features and advantages of the present invention will become apparent in the following detailed description of the preferred embodiments of this invention, with reference to the accompanying drawings, in which:

FIGS. 1 to 3 are views to illustrate a method of making a conventional epitaxial structure;

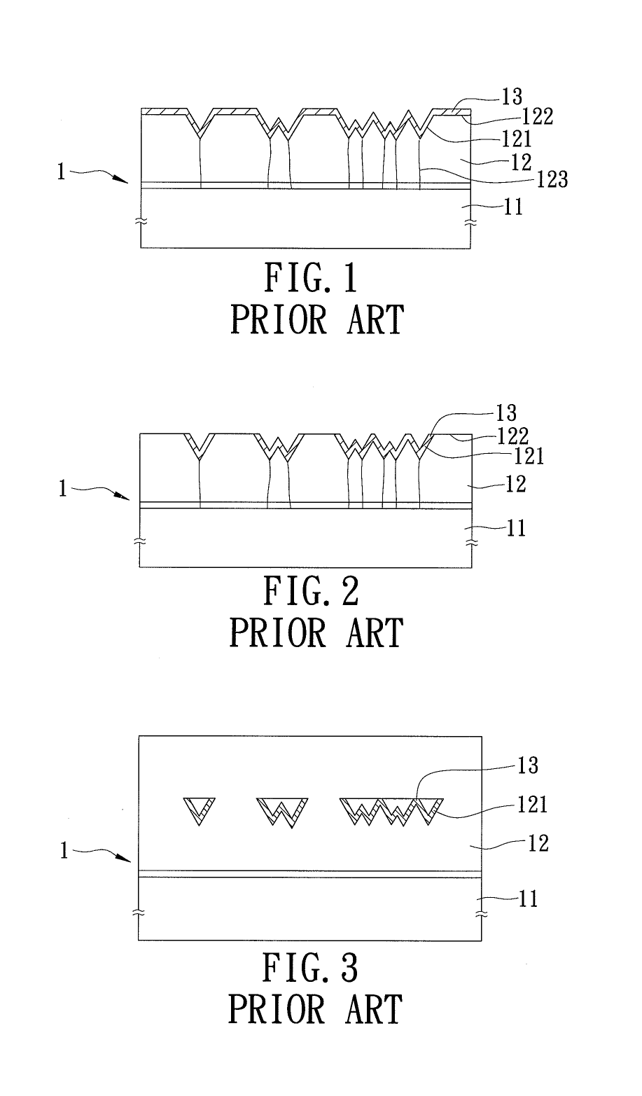

FIG. 4 is a schematic view of the first preferred embodiment of an epitaxial structure according to this invention;

FIGS. 5a to 5g are views to illustrate consecutive steps of the first preferred embodiment of a method of making the epitaxial structure according to this invention;

FIG. 6 is an image of a recess formed in the epitaxial layer of the first preferred embodiment of the present invention;

FIG. 7 is the same view as FIG. 4, but illustrating second recesses being rectangular in cross-section;

FIG. 8 is the same view as FIG. 4, but illustrating second recesses being trapezoidal in cross-section;

FIG. 9a is an image showing non-uniform recesses of the first preferred embodiment of the present invention when the base layer is not patterned;

FIG. 9b is an image showing uniform recesses of the first preferred embodiment of the present invention when the base layer is patterned; and

FIG. 10 is a schematic view of the second preferred embodiment of the epitaxial structure according to this invention.

### DETAILED DESCRIPTION OF THE PREFERRED EMBODIMENTS

Before the present invention is described in greater detail with reference to the accompanying preferred embodiments, it should be noted herein that like elements are denoted by the same reference numerals throughout the disclosure.

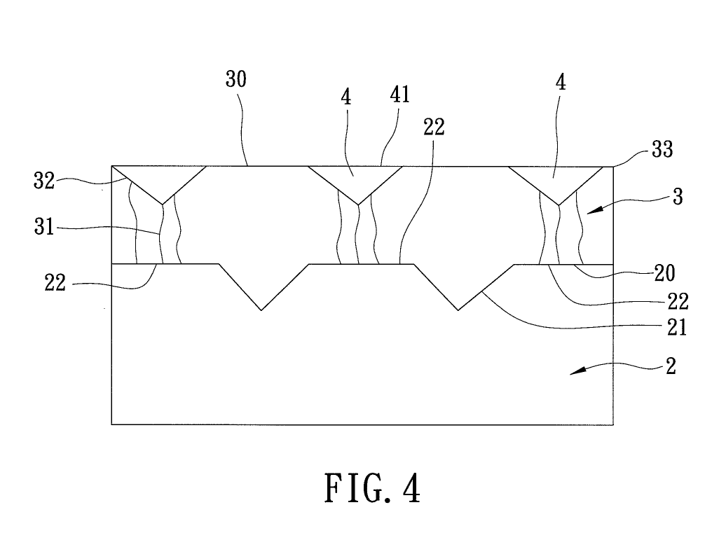

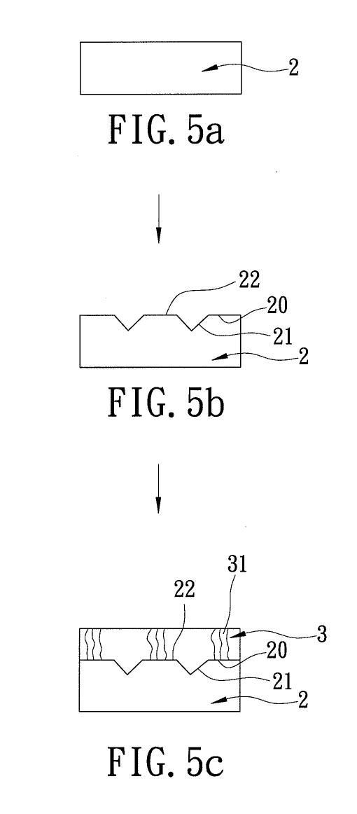

Referring to FIGS. 4 and 5g, there is shown the first preferred embodiment of an epitaxial structure having a low defect density according to this invention. The epitaxial structure includes a base layer 2, a first epitaxial layer 3 having a plurality of first recesses 32, a plurality of defect-termination blocks 4, and a second epitaxial layer 5.

The base layer 2 is patterned, and has a lattice mismatch with the first epitaxial layer 3, and a base surface 20 that includes a plurality of second recesses 21 and a plurality of flat surface portions 22 among the second recesses 21. The second recesses 21 are arranged in a matrix array, and have an average width ranging from 1 μm to 5 μm and an average depth not less than one fifth of the average width.

It is worth mentioning that the base layer 2 may have a flat surface which is not patterned. However, when the base layer 2 is patterned, defects originated from the lattice mismatching have a high tendency to spontaneously concentrate on the flat surface portions 22 during growth of an epitaxial layer. As an alternative to the second recesses 21, the pattern of the base layer 2 may include strip-like pattern elements or irregular pattern elements (not shown).

The first epitaxial layer 3 is laterally grown from the flat surface portions 22 and is made from gallium nitride (GaN). Alternatively, the first epitaxial layer 3 is a multilayer structure containing at least one nitride-based layer. The nitride-based layer includes a nitride compound selected from the group consisting of gallium nitride (GaN), aluminum nitride (AlN), aluminum gallium nitride (AlₓGa₁₋ₓN, 0≦X≦1), or combinations thereof. The first epitaxial layer 3 includes a plurality of concentrated defect groups 31, and an epitaxial surface 30 that has the first recesses 32 formed thereon corresponding in position to the top ends of the concentrated defect groups 31. The concentrated defect groups 31 are concentrated on the flat surface portions 22. The density of defects (not shown) is relatively low above the second recesses 21.

Preferably, the first recesses 32 have an average width ranging from 1 μm to 6 μm, more preferably, ranging from 2 μm to 4 μm, and most preferably, the first recesses 32 have an average width of 3 μm. The first recesses 32 have an average depth greater than 0.2 μm, and a standard deviation from the average depth of the first recesses 32 is not larger than 0.13 μm.

The defect-termination blocks 4 respectively and completely fill the first recesses 32 and have polished surfaces 41. The polished surfaces 41 are substantially flush with the epitaxial surface 30 to provide a substantially planarized crystal growth surface 33.

FIGS. 5a to 5g illustrate the consecutive steps of the first preferred embodiment of a method of making the epitaxial structure according to this invention.

Referring to FIGS. 5a and 5b, the base layer 2 is patterned and is formed with the second recesses 21 through lithography techniques. The second recesses 21 are indented from the base surface 20 and are spaced apart from each other.

Referring to FIG. 5c, the first epitaxial layer 3 is formed on the patterned base layer 2 using lateral overgrowth techniques. The second recesses 21 may or may not be filled completely by the first epitaxial layer 3. Defects of the first epitaxial layer 3 will concentrate on the flat surface portions 22 either the second recesses 21 are filled completely or not. The defect density of the first epitaxial layer 3 is low on the second recesses 21 compared to that on the flat surface portions 22.

Referring to FIG. 5d, the first epitaxial layer 3 is etched using a wet etching agent so that the first epitaxial layer 3 has the first recesses 32 corresponding in position to the concentrated defect groups 31. Since the etching is carried out without using any mask, difficulties encountered in alignment of the mask can be avoided.

It is worth mentioning that, the depth etched by the wet etching agent is larger in portions of the first epitaxial layer 3 where the defects are concentrated than in portions of the first epitaxial layer 3 where the density of the defects is low.

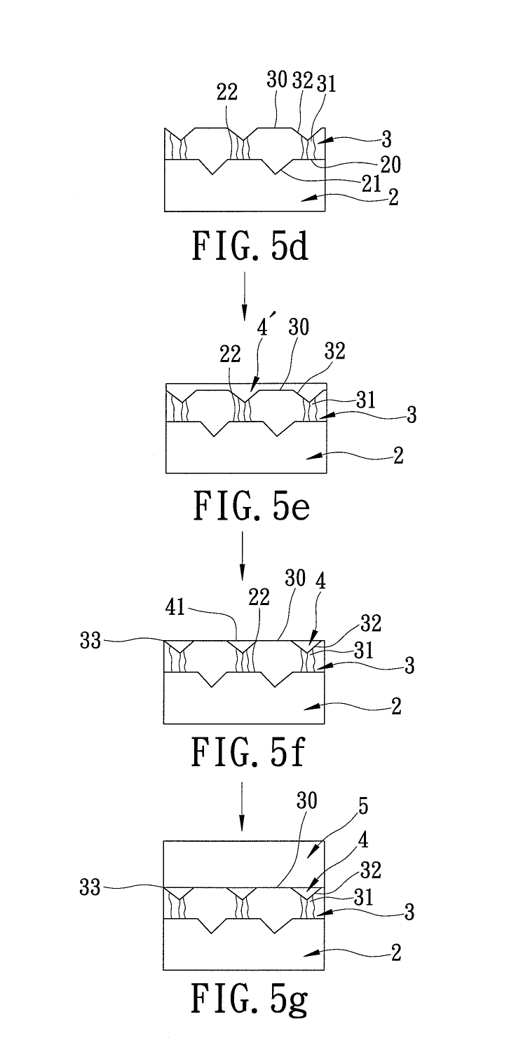

In this embodiment, the wet etching agent contains heated phosphoric acid, and has no sulfuric acid. Such etching agent can form hexagonal holes in the first epitaxial layer 3 when the defects are screw dislocations, but does not etch the first epitaxial layer 3 when the defects are edge dislocations. Accordingly, the first recesses 32 are formed on top ends of the screw dislocations. The first recesses 32 are hexagonal (see FIG. 6) when viewed from a top side of the first epitaxial layer 3, and are triangular in cross-section (see FIG. 4) when the first epitaxial layer 3 is sectioned along a vertical plane. The triangular cross section can be produced at initial time of wet etching. After wet etching is conducted out for a period of time, the cross section of the first recesses 32 can become trapezoidal or even irregular. Each of the concentrated defect groups 31 includes the screw dislocations.

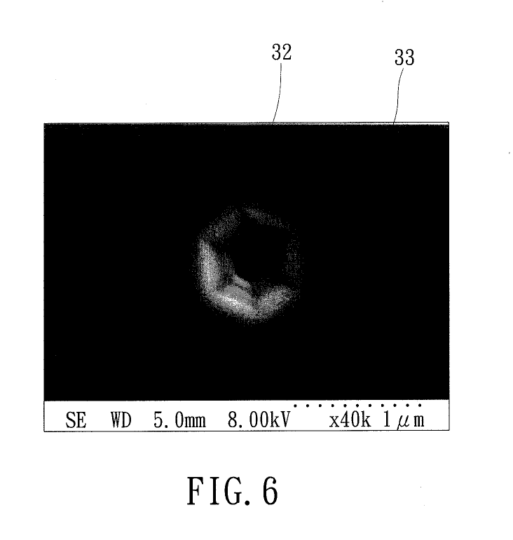

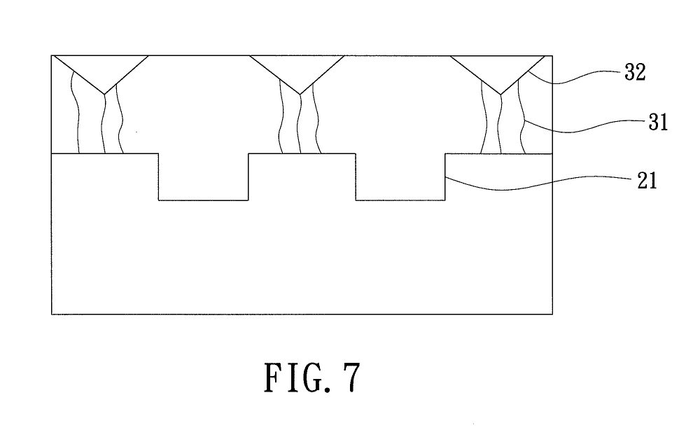

The second recesses 21 are triangular in cross-section (see FIG. 4) when formed by wet etching, and are rectangular, or trapezoidal (see FIGS. 7 and 8) when formed by dry etching.

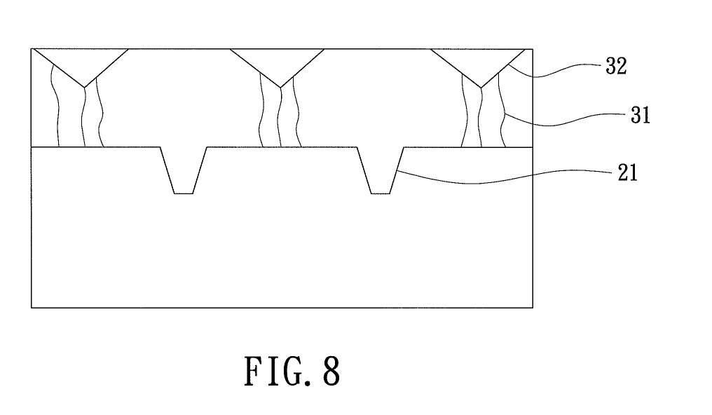

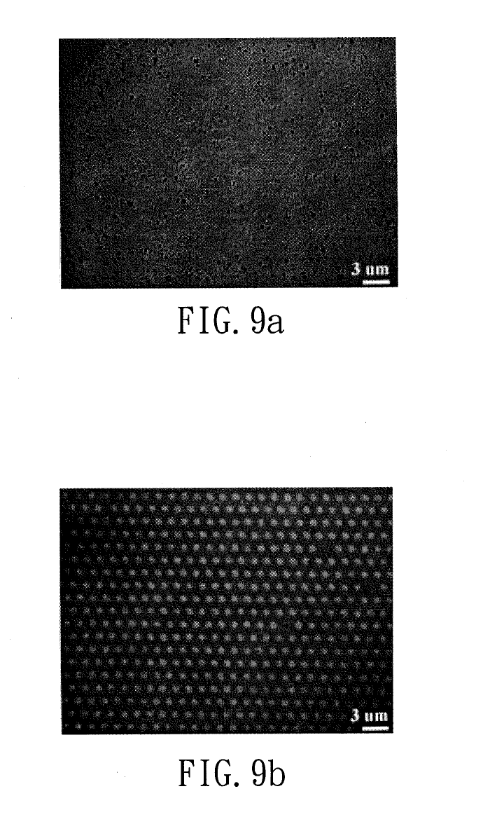

Referring to FIG. 9a, if the base layer 2 is not patterned for growth of the first epitaxial layer 3 thereon, the screw dislocations in the first epitaxial layer 3 can not be sufficiently concentrated during growth of the first epitaxial layer 3 so that the first recesses 32 cannot have uniform and sufficiently deep depth. On the contrary, referring to FIG. 9b, if the base layer 2 is patterned, the first recesses 32 can have uniform and deep depth, which is beneficial to prevent propagation of the defects therefrom.

In order to provide the first recesses 32 with a uniform size, the etching temperature is preferably not greater than 270° C. More preferably, the etching temperature is 200° C. so that the etching rate can be reduced. As a result, the first recesses 32 can have more uniform size, and the first recesses 32 can be prevented from merging. If the first recesses 32 merge, because the width of the recesses 32 and the size of the defect-termination blocks 4 will become large, the second epitaxial layer 5 (FIG. 5g) cannot make a good bonding at the positions where the large recesses exist.

Referring to FIG. 5e, after etching, a defect-termination layer 4′ having a thickness larger than the depth of the first recesses 32 is deposited on the first epitaxial layer 3 so that the defect-termination layer 4′ completely fills the first recesses 32 and covers the epitaxial surface 30.

Referring to FIG. 5f, the defect-termination layer 4′ is removed by a chemical mechanical polishing process (CMP) until the epitaxial surface 30 is exposed, thereby forming a plurality of defect-termination blocks 4 that respectively and completely fill the first recesses 32 whereby the defect-termination blocks 4 have polished surfaces 41 that are substantially flush with the epitaxial surface 30 to provide the substantially planarized crystal growth surface 33. In this embodiment, a slurry containing colloidal silicon dioxide is used for the CMP process.

The defect-termination layer 4′ that forms the defect-termination blocks 4 is made of a material which is different in removal rate from that of the first epitaxial layer 3.

Preferably, the defect-termination layer 4′ is made from a material selected from the group consisting of an oxide, a nitride, a fluoride, a carbide, and combinations thereof. More preferably, the defect-termination layer 4′ is made from a material selected from the group consisting of silicon dioxide, silicon nitride, titanium dioxide, and combinations thereof. In this embodiment, the defect-termination layer 4′ is made from silicon dioxide.

In order to obtain good polishing effect, during the chemical mechanical polishing, the base layer 2 and the first epitaxial layer 3 are flattened by attaching the base layer 2 to a planar plate (not shown). In this embodiment, the planar plate is made of crystal wax, and the base layer 2 is adhered to the planar plate through a high vacuum pressure suction at a heated temperature.

Compared to other methods, such as ion reactive etching, the chemical mechanical polishing can remove the defect-termination layer 4′ uniformly and quickly. The removal rate of the defect-termination layer 4′ is different from that of the first epitaxial layer 3. Because the chemical mechanical polishing can also remove the first epitaxial layer 3 when removing the defect-termination layer 4′, the defect-termination layer 4′ should be made from a material that can be removed faster than the first epitaxial layer 3. Due to the presence of the defect-termination blocks 4, the epitaxial surface 30 of the first epitaxial layer 3 has a low defect density.

Referring to FIG. 5g, the second epitaxial layer 5 is formed on the crystal growth surface 33. Since the concentrated defect groups 31 are terminated by the defect-termination blocks 4, the second epitaxial layer 5 grown on the crystal growth surface 33 will have a defect density relatively lower than that of the first epitaxial layer 3, and is suitable for subsequent growth of semiconductor devices, such as a light-emitting device, a high-frequency communication device, and a field effect transistor, thereon.

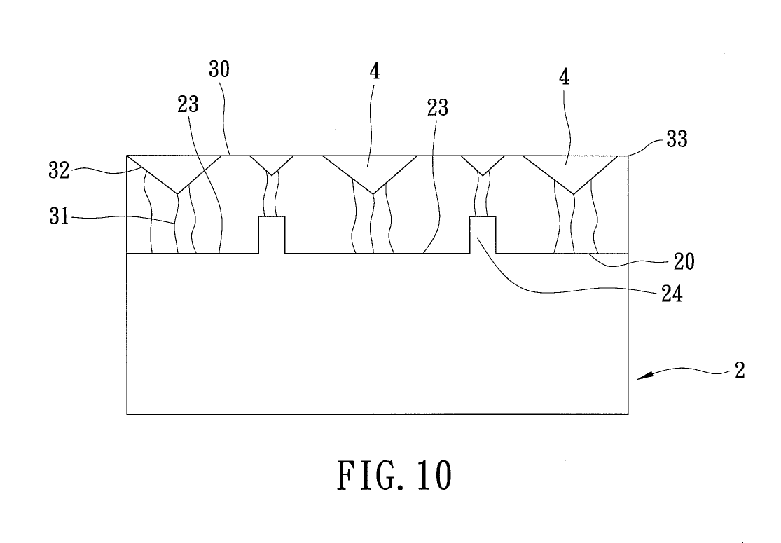

Referring to FIG. 10, the second preferred embodiment of the present invention differs from the first embodiment in that the base layer 2 is patterned to form a plurality of protrusions 24 protruding from the base surface 20 and a plurality of protrusion-free surface portions 23. The concentrated defect groups 31 are formed corresponding in position to the protrusion-free surface portions 23, and the first epitaxial layer 3 has a relatively low defect density on the protrusions 24.

While the present invention has been described in connection with what are considered the most practical and preferred embodiments, it is understood that this invention is not limited to the disclosed embodiments but is intended to cover various arrangements included within the spirit and scope of the broadest interpretation so as to encompass all such modifications and equivalent arrangements.

What is claimed is:

1. A method of making an epitaxial structure that has a low defect density, comprising:
(a) forming a first epitaxial layer on a base layer, the first epitaxial layer having an epitaxial surface and a plurality of concentrated defect groups;
(b) etching the first epitaxial layer using a wet etching agent so that the epitaxial surface has a plurality of first recesses corresponding in position to the concentrated defect groups, the sizes of the first recesses being close to each other;
(c) depositing on the first epitaxial layer a defect-termination layer having a thickness larger than the depth of the first recesses so that the defect-termination layer fills the first recesses and covers the epitaxial surface, the defect-termination layer being made of a material which is different in removal rate from that of the first epitaxial layer; and
(d) removing the defect-termination layer by a chemical mechanical polishing process until the epitaxial surface is exposed, thereby forming a plurality of defect-termination blocks that respectively and completely fill the first recesses, wherein the defect-termination blocks have polished surfaces that are substantially flush with the epitaxial surface.

2. The method of claim 1, further comprising patterning the base layer prior to step (a).

3. The method of claim 2, wherein the patterned base layer is formed with a plurality of spaced apart second recesses, and a plurality of flat surface portions among the second recesses.

4. The method of claim 3, wherein the second recesses are arranged in a matrix array, and have an average width ranging from 1 μm to 5 μm and an average depth not less than one fifth of the average width.

5. The method of claim 2, wherein the patterned base layer is formed with a plurality of spaced apart protrusions.

6. The method of claim 1, wherein, in step (b), the etching is carried out without using any mask.

7. The method of claim 6, wherein the wet etching agent is phosphoric acid, and the first epitaxial layer is made from gallium nitride.

8. The method of claim 1, wherein the first recesses have an average depth greater than 0.2 μm.

9. The method of claim 8, wherein a standard deviation from the average depth of the first recesses is not larger than 0.13 μm.

10. The method of claim 1, wherein the first recesses have an average width ranging from 1 μm to 6 μm.

11. The method of claim 10, wherein the first recesses have an average width ranging from 2 μm to 4 μm.

12. The method of claim 11, wherein the first recesses have an average width of 3 μm.

13. The method of claim 1, wherein the defect-termination layer is made from a material selected from the group consisting of an oxide, a nitride, a fluoride, a carbide, and combinations thereof.

14. The method of claim 1, further comprising flattening the base layer and the first epitaxial layer by attaching the base layer to a planar plate before the chemical mechanical polishing process is conducted.

15. The method of claim 1, further comprising forming a second epitaxial layer on the first epitaxial layer, the second epitaxial layer having a defect density lower than that of the first epitaxial layer.

16. The method of claim 1, wherein the concentrated defect groups include screw dislocations, and the first recesses are formed on top ends of the screw dislocations.
